(19) United States
(12) Patent Application Publication
(10) Pub. No.: US 2025/0133718 A1
(43) Pub. Date: Apr. 24, 2025

(54) SEMICONDUCTOR DEVICE AND MANUFACTURING METHOD THEREOF

(71) Applicant: NANYA TECHNOLOGY CORPORATION, New Taipei city (TW)

(72) Inventor: Jhen-Yu TSAI, Kaohsiung City (TW)

(21) Appl. No.: 18/489,459

(22) Filed: Oct. 18, 2023

(51) Int. Cl. H10B 12/00

(52) U.S. Cl. CPC H10B 12/315; H10B 12/05

(57) ABSTRACT

A semiconductor device includes a bit line, a source, a body, a channel, a drain, a word line and a first body contact. The source is on the bit line. The body is on the source. The channel is on the body. The drain is on the channel. The word line surrounds and is spaced apart from the channel. The first body contact is on the body, in which the first body contact and the source are separated by the body.

### BACKGROUND

### Field of Disclosure

The present disclosure relates to a semiconductor device and a manufacturing method thereof.

### Description of Related Art

The carrier stored in the floating body cell (FBC) is mainly generated by the impact ionization operated like channel hot-electron injection near drain side. The impact ionization creates electron and hole pairs, where electrons are withdrawn by drain, while holes are swept toward the floating body as a transient storage for n-channel devices. The OFF-state leakage current was considerably high due to the parasitic BJT operation in the accumulated holes of the body.

### SUMMARY

Some embodiments of the present disclosure provide a semiconductor device including a bit line, a source, a body, a channel, a drain, a word line and a first body contact. The source is on the bit line. The body is on the source. The channel is on the body. The drain is on the channel. The word line surrounds and is spaced apart from the channel. The first body contact is on the body, in which the first body contact and the source are separated by the body.

In some embodiments, the first body contact is adjacent to a first side of the channel.

In some embodiments, the semiconductor device further includes a second body contact adjacent to a second side of the channel, in which the second side is opposite to the first side.

In some embodiments, a top surface of the first body contact is level with a top surface of the drain.

In some embodiments, the semiconductor device further includes a dielectric layer extending from a sidewall of the drain, passing through a sidewall of the channel and a top surface of the body, to the first body contact.

In some embodiments, the semiconductor device further includes an isolation structure surrounding the first body contact and in contact with the dielectric layer.

In some embodiments, a top surface of the first body contact is level with a top surface of the isolation structure.

In some embodiments, a bottom surface of the first body contact is level with a bottom surface of the channel.

In some embodiments, the semiconductor device further includes a capacitor on the drain.

In some embodiments, the semiconductor device further includes a terminal on the first body contact.

In some embodiments, the first body contact extends from the body to the terminal.

Some embodiments of the present disclosure provide a manufacturing method of a semiconductor device including sequentially forming a bit line, a source, a body, a channel material layer and a drain material layer, in which the source is on the bit line, the body is on the source, the channel material layer is on the body, and the drain material layer is on the channel material layer. First trenches are formed in the channel material layer and the drain material layer to expose the body, in which remaining portions of the channel material layer and the drain material layer form channels and drains. A dielectric layer is formed lining the first trenches. The word lines surrounding the channels are formed, in which the word lines and the channels are separated by the dielectric layer. Isolation structures are formed in the first trenches. Body contacts are formed in the isolation structures, in which the body contacts are in contact with the body.

In some embodiments, the manufacturing method further includes forming a second trench in the source, the body, the channel material layer and the drain material layer to expose the bit line after forming the first trenches.

In some embodiments, the manufacturing method further includes forming capacitors on the drains.

In some embodiments, the manufacturing method further includes forming terminals on the body contacts.

In some embodiments, forming the body contacts includes forming third trenches in the isolation structures and the dielectric layer and exposing the body, and filling a p-type heavily doped material in the third trenches to form the body contacts.

In some embodiments, the body contacts are in contact with the isolation structures and the dielectric layer.

In some embodiments, bottoms of the third trenches are level with bottom surfaces of the channels, so that the bottoms surfaces of the body contacts are level with bottom surfaces of the channels.

In some embodiments, top surfaces of the body contacts are level with top surfaces of the drains.

In some embodiments, top surfaces of the body contacts are level with top surfaces of the isolation structures.

A semiconductor device with body contacts is provided in some embodiments of the present disclosure. The body contacts and the locations thereof are used to reduce the OFF-state leakage current of the device.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a top view of a semiconductor device in some embodiments of the present disclosure.

FIG. 2 illustrates a cross-section view of the semiconductor device taken along line A-A in FIG. 1 in some embodiments of the present disclosure.

FIGS. 3-10 illustrate cross-section views of manufacturing method of the semiconductor device in some embodiments of the present disclosure.

FIG. 11 illustrates a top view of a semiconductor device in some other embodiments of the present disclosure.

FIG. 12 illustrates a cross-section view of the semiconductor device taken along line B-B in FIG. 11 in some other embodiments of the present disclosure.

FIG. 13 illustrates a top view of a semiconductor device in some other embodiments of the present disclosure.

FIG. 14 illustrates a cross-section view of the semiconductor device taken along line C-C in FIG. 13 in some other embodiments of the present disclosure.

### DETAILED DESCRIPTION

A semiconductor device with body contacts is provided in some embodiments of the present disclosure. The semiconductor device may be vertical dynamic random-access memory (DRAM) in some embodiments. The body contacts and the locations thereof are used to reduce the OFF-state leakage current of the device.

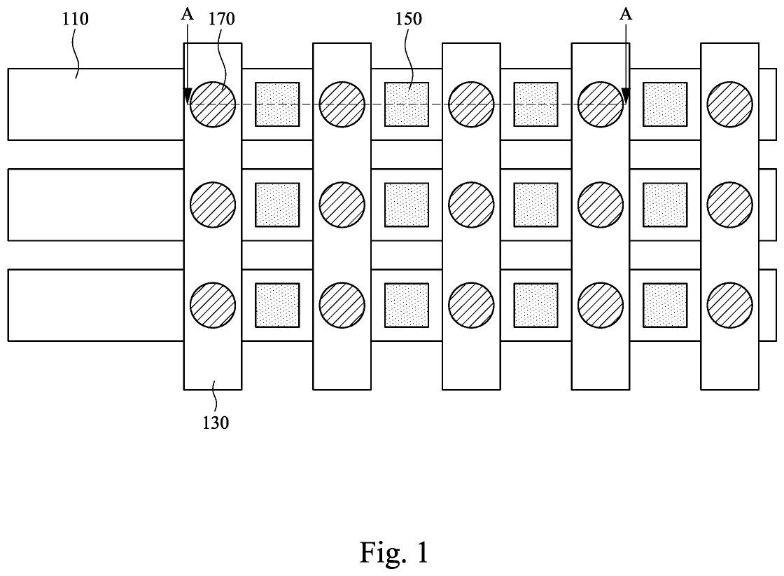

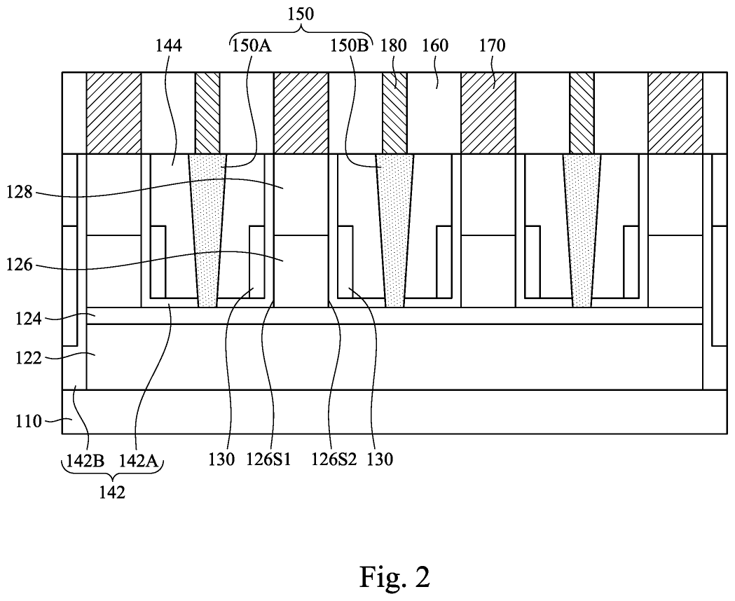

FIG. 1 illustrates a top view of a semiconductor device in some embodiments of the present disclosure. FIG. 2 illustrates a cross-section view of the semiconductor device taken along line A-A in FIG. 1 in some embodiments of the present disclosure. It is noted that FIG. 1 only illustrates bit lines 110, word lines 130, capacitors 170 and body contacts 150 for simplicity, and the detailed structure of the semiconductor device is shown in FIG. 2.

The semiconductor device includes a bit line 110, a source 122 on the bit line 110, a body 124 on the source 122, channels 126 on the body 124, drains 128 on channels 126, word lines 130 surrounding and spaced apart from the respective channels 126, and body contacts 150 on the body 124. The body contacts 150 and the sources 122 are separated from each other by the body 124. The top surfaces of the body contacts 150 are substantially level with top surfaces of the drains 128. The bit lines 110 and the word lines 130 are arranged in perpendicular directions as shown in FIG. 1.

The semiconductor device further includes dielectric layers 142 and isolation structures 144. The dielectric layers 142 surround the respective channels 126 and may serve as gate dielectric layer of a transistor. The dielectric layers 142 are between the channels 126 and the word lines 130. In some embodiments, the dielectric layers 142 include portions 142A in contact with the top surface of the body 124 and portions 142B in contact with the top surface of the bit line 110. The isolation structures 144 surround the body contacts 150 and are in contact with the dielectric layers 142. The isolation structures 144 also cover the word lines 130. The semiconductor device further includes a dielectric layer 160, capacitors 170 and terminals 180. The capacitors 170 are on the drains 128, and the terminals 180 are on the body contacts 150. The capacitors 170 and the terminals 180 are separated by the dielectric layer 160. In some embodiments, the terminals 180 may be connected with VBB (i.e. the base supply voltage in a transistor circuit).

The semiconductor device further includes capacitors 170 disposed on and electrically connected to the respective drains 128. In some embodiments where the semiconductor device is a memory device (e.g., DRAM), the memory may include a plurality of memory cell. A typical DRAM cell incorporates a capacitor and a transistor in which the capacitor temporarily store data based on the charged state of the capacitor. A bit line is electrically connected to a source region of the transistor, and a word line is electrically connected to a gate region of the transistor. In some embodiments, the transistor of each memory cell may include the source 122, the body 124, the channel 126, the drain 128, and the dielectric layer 142 (e.g., gate dielectric layer). The word line 130 may also serve as the gate of the transistor. On the assumption that a pitch of each of word line 130 and bit line 110 is 2F, a horizontal size of DRAM cell can be 4F2, which means that the DRAM cell can have an area of approximately 4F2 or less, where F is the minimum lithographic feature size.

The body contacts 150 extend from the body 124 to the terminals 180 and are used to reduce the OFF-state leakage current in the semiconductor device by introducing the accumulated holes out of the body 124 to the terminals 180, so the OFF-state leakage current may be reduced. In some embodiments, the body contact 150 includes a first body contact 150A and a second body contact 150B. The first body contact 150A is adjacent to a first side 126S1 of the channel 126, the second body contact 150B is adjacent to a second side 126S2 of the channel 126, and the second side 126S2 is opposite to the first side 126S1. Both the first body contact 150A and the second body contact 150B are spaced apart from the channel 126. That is, the channel 126 is between the first body contact 150A and the second body contact 150B. In some embodiments, the body contact 150 is made of P-type heavily doped material, the body 124 is made of P-type lightly doped material, and the source 122 is made of N-type heavily doped material. Therefore, the body contacts 150 are not in contact with the source 122, and an interface between P-type heavily doped region and N-type heavily doped region is not existed, and the OFF-state leakage current will be further reduced.

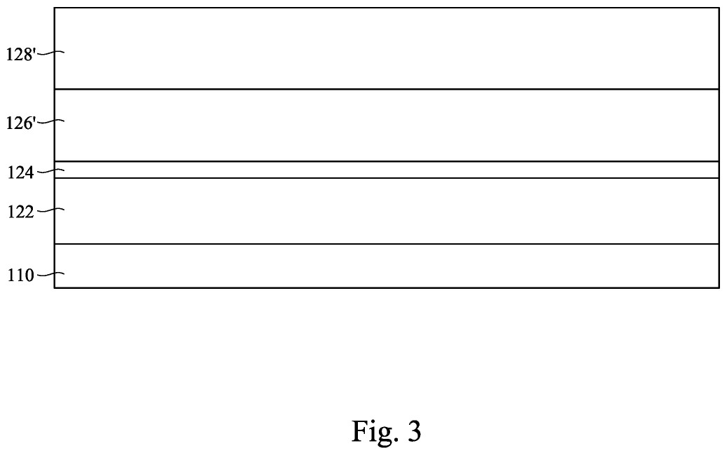

FIGS. 3-10 illustrate cross-section views of manufacturing method of the semiconductor device in some embodiments of the present disclosure. Referring to FIG. 3, a bit line 110, a source 122, a body 124, a channel material layer 126′ and a drain material layer 128′ are sequentially formed. That is, the source 122 is on the bit line 110, the body 124 is on the source 122, the channel material layer 126′ is on the body 124, and the drain material layer 128′ is on the channel material layer 126′. In some embodiments, the bit line 110 is made of metal, such as tungsten (W), copper (Cu), or molybdenum (Mo), but is not limited thereto. The source 122, the body 124, the channel material layer 126′, and the drain material layer 128′ may be made of semiconductor materials. For example, the source 122 and the drain material layer 128′ may be made of N-type heavily doped silicon layer, the body 124 may be made of P-type lightly doped silicon layer, and the channel material layer 126′ may be made of P-type moderately doped silicon layer.

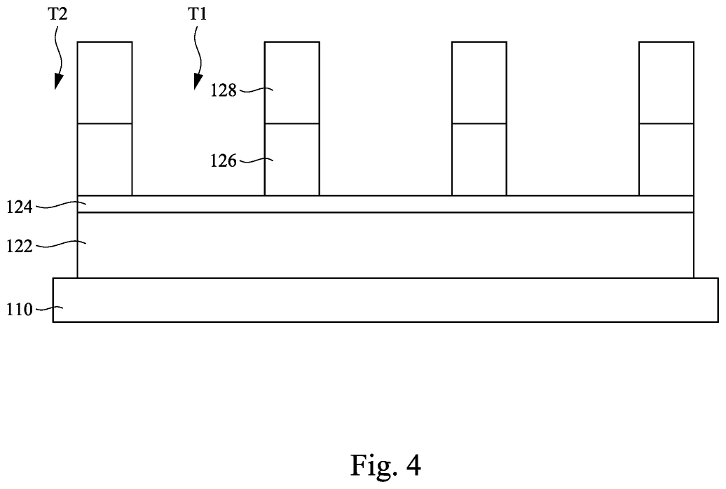

Referring to FIG. 4, first trenches T1 are formed in the channel material layer 126′ and the drain material layer 128′ to expose the body 124 and form channels 126 and drains 128. Second trenched T2 are formed in the source 122, the body 124, the channel material layer 126′ and the drain material layer 128′ to expose the bit line 110 after forming the first trenches T1. In some embodiments, the second trenches T2 may be formed before forming the first trenches T1. The second trench T2 may be adjacent to one of the first trenches T1. The bottom of the second trenches T2 is lower than the bottom of the first trenches T1. The remaining portions of the channel material layer 126′ and the drain material layer 128′ serve as channels 126 and drains 128 as discussed with respect to FIG. 2.

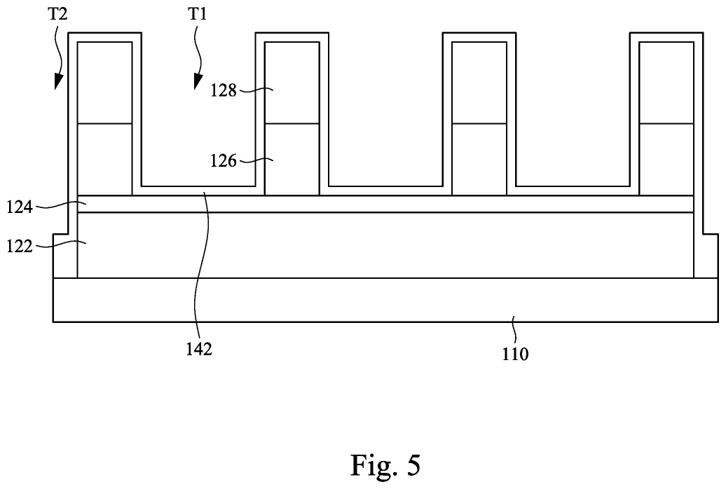

Referring to FIG. 5, dielectric layers 142 are formed lining the first trenches T1 and the second trenches T2 and the top surface of the drains 128. In some embodiments, the dielectric layers 142 are made of silicon oxide, silicon nitride, or the like.

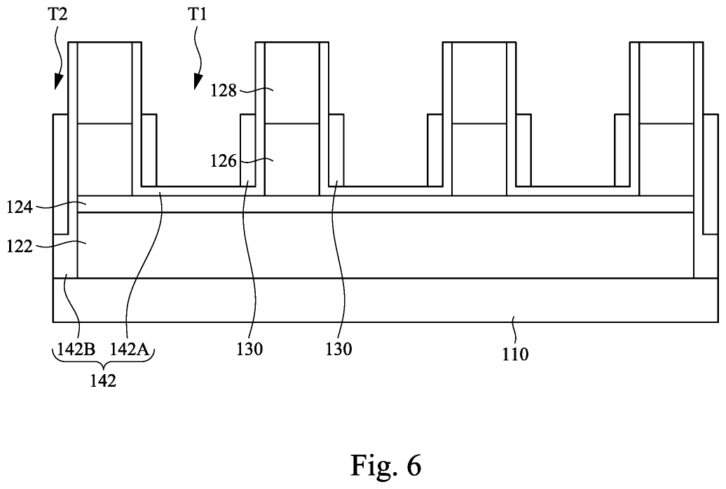

Referring to FIG. 6, the word lines 130 surrounding the channels 126 are formed, in which the word lines 130 and the channels 126 the dielectric layer 142. More specifically, a word line material layer may be first formed in the first trenches T1 and the second trenches T2. Subsequently, the word line material layer is patterned to form the word lines 130 surrounding the channels 126. In some embodiments, the word lines 130 may also surround a portion of the drains 128. Since the bottom of the second trenches T2 is lower than the bottom of the first trenches T1, a bottom of the word line 130 in the second trench T2 is lower than a bottom of the word line 130 in the first trenched T1. In some embodiments, the word lines 130 may be made of metal, such as tungsten (W), copper (Cu), or molybdenum (Mo), but is not limited thereto. After forming the word lines 130, the dielectric layer 142 lining the top surface of the drains 128 are removed by a cleaning process, and the dielectric layer 142 includes portions 142A in the first trenches T1 and portions 142B in the second trenches T2.

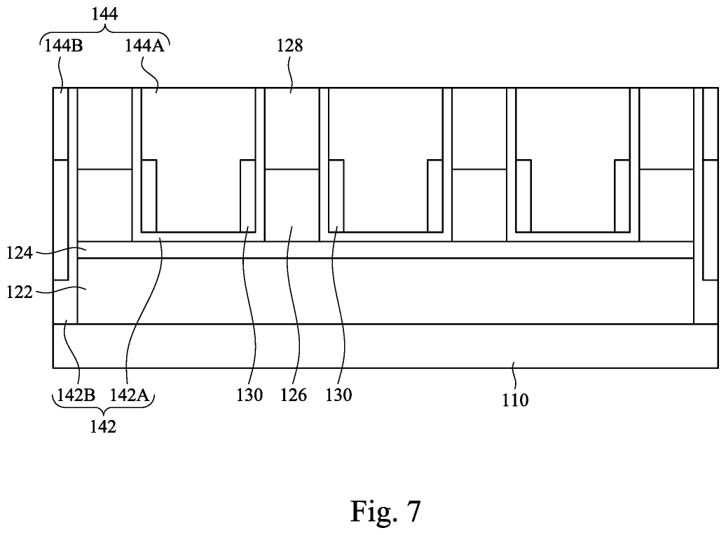

Referring to FIG. 7, isolation structures 144 are formed in the first trenches T1 and the second trenches T2. The isolation structures 144 include first portions 144A in the first trenches T1 (see FIG. 6), and the second portions 144B in the second trenches T2 (see FIG. 6). Specifically, dielectric material may be firstly filled in the first trenches T1 and the second trenches T2. Then, a planarization process is performed to remove excess material of the dielectric material outside the first trenches T1 and the second trenches T2, such that top surfaces of the isolation structures 144 are substantially level with top surfaces of the drains 128. In some embodiments, the isolation structures 144 are made of silicon oxide, silicon nitride, or the like.

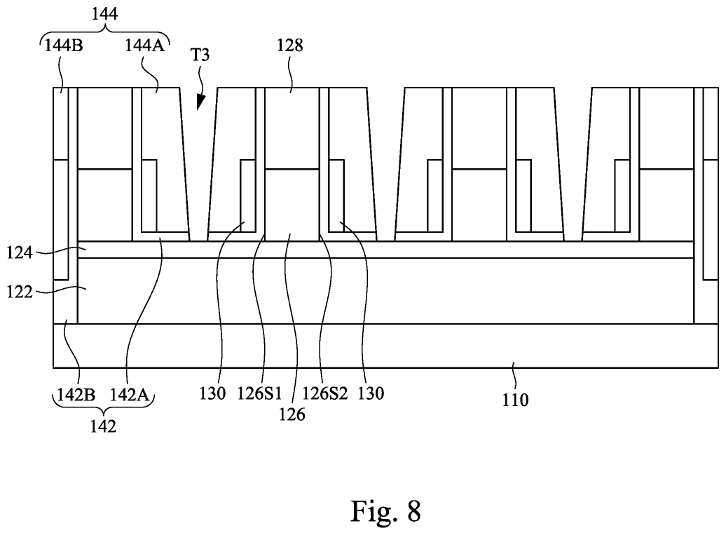

Referring to FIG. 8, third trenches T3 are formed in the first portions 144A of the isolation structures and the dielectric layer 142, and the third trenches T3 expose the body 124. Therefore, bottom surfaces of the third trenches T3 are also level with bottom surfaces of the channels 126. The third trenches T3 are spaced apart from the word lines 130 and the channels 126. That is, the third trenches T3 do not expose the word lines 130 and the channels 126. In some embodiments, the third trenches T3 may be formed adjacent to the first side 126S1 and the second side 126S2 of the channel 126.

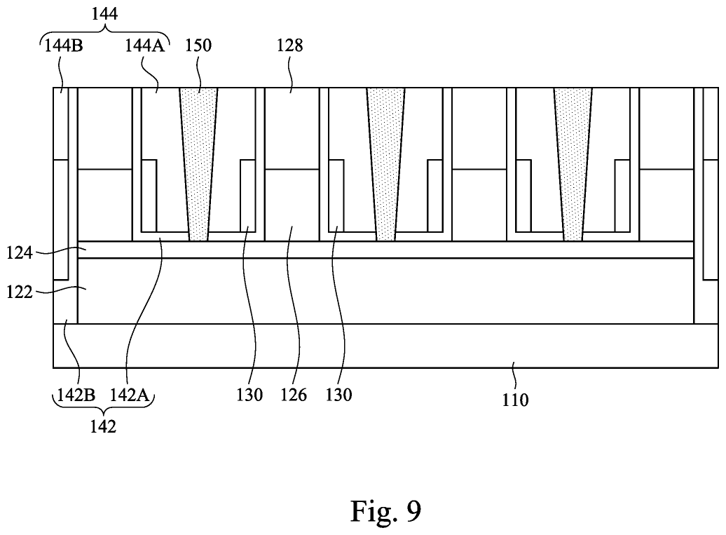

Referring to FIG. 9, a p-type heavily doped material is filled in the third trenches T3 (see FIG. 8) to form the body contacts 150 in the third trenches T3. Then, a planarization process is performed to remove excess material of the p-type heavily doped material outside the third trenches T3, such that top surfaces of the body contacts 150 are substantially level with the top surfaces of the drains 128 and the top surfaces of the isolation structures 144. In some embodiments, p-type heavily doped material may be made of polysilicon doped with boron or gallium. In some other embodiments, metal rather than p-type heavily doped material is filled in the third trenches T3 (see FIG. 8) to form the body contacts 150. The body contacts 150 are in contact with the isolation structures 144 and the dielectric layers 142. Moreover, the body contacts 150 are wrapped by the first portions 144A of the isolation structures 144, and are separated from the word lines 130 by the first portions 144A of the isolation structures 144. The dielectric layers 142 extends from sidewalls of the drains 128, passing through sidewalls of the channel 126 and a top surface of the body 124, to the body contacts 150, after the p-type heavily doped material or metal is filled in the trenches T3, and the bottom surfaces of the body contacts 150 are level with the bottom surfaces of the channels 126. The body contacts 150 are in contact with the body 124, and are used to introduce the accumulated holes out of the body 124, so the OFF-state leakage current may be reduced. The body contacts 150 and the sources 122 are separated by the body 124. That is, the body contacts 150 are not in contact with the source 122. Therefore, in some embodiments where the body contacts 150 are made of P-type heavily doped material, the interface between P-type heavily doped region (i.e. body contacts 150) and N-type heavily doped region (i.e. source 122) is not existed. The OFF-state leakage current will further be reduced.

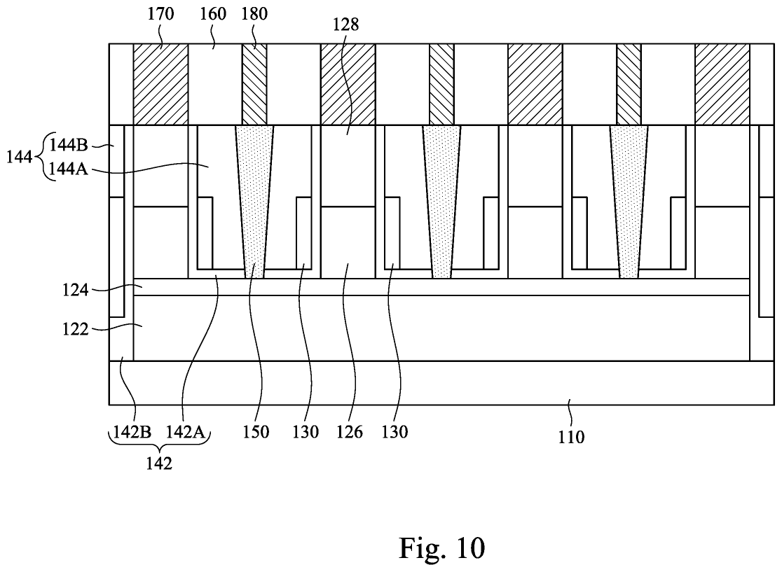

Referring to FIG. 10, the capacitors 170 are formed on the drains 128, and the terminals 180 are formed on the body contacts 150. More specifically, a dielectric layer is first formed on the structure shown in FIG. 9. Subsequently, multiple trenches are formed in the dielectric layer to expose the drains 128 and the body contacts 150, and the dielectric layer 160 is formed. In some embodiments, the trenches exposing the drains 128 and the trenches exposing the body contacts 150 are not formed at the same time. Subsequently, the capacitors 170 are formed on the drains 128, and the terminals 180 are formed on the body contacts 150. The capacitors 170 and the terminals 180 are separated by the dielectric layer 160. It is noted that the structures of the capacitors 170 are simplified in FIG. 10. In some embodiments, the capacitors 170 may be multilayer structures.

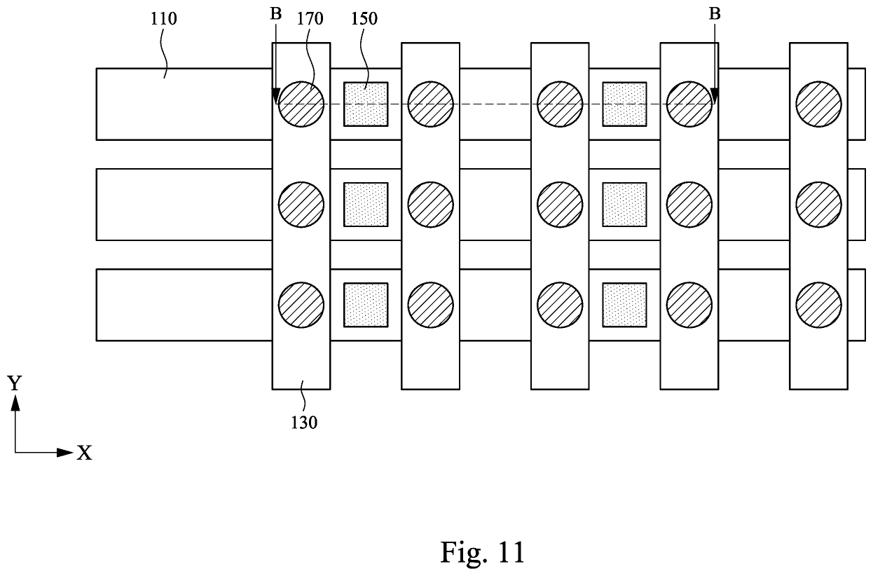

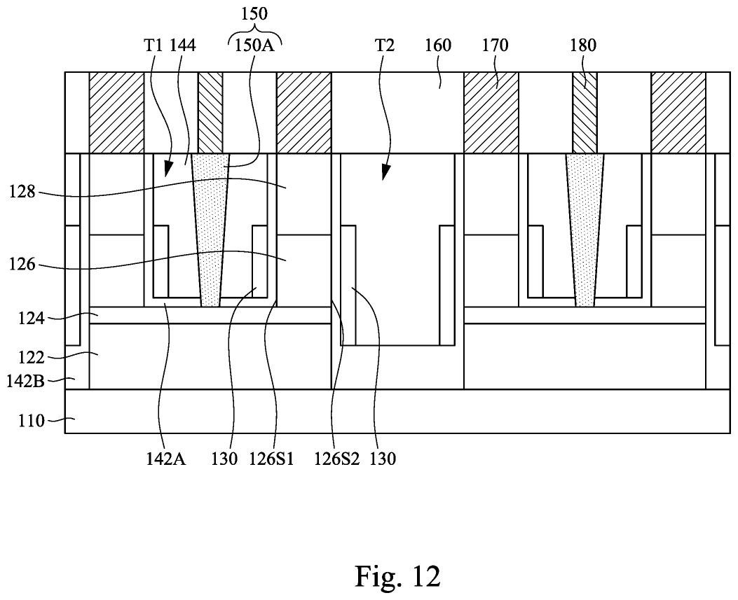

FIG. 11 illustrates a top view of a semiconductor device in some other embodiments of the present disclosure. FIG. 12 illustrates a cross-section view of the semiconductor device taken along line B-B in FIG. 11 in some other embodiments of the present disclosure. The semiconductor device in FIGS. 11-12 is similar to the semiconductor device in FIGS. 1-2. The difference is that the semiconductor device in FIGS. 11-12 does not include the second body contact 150B. In FIGS. 11-12, the first body contact 150A is adjacent to the first side 12651 of the channel 126, and there is no body contact adjacent to the second side 12652 of the channel 126. The manufacturing method of the semiconductor device in FIGS. 11-12 is also similar to the manufacturing method of the semiconductor device in FIGS. 1-2 (i.e. the manufacturing method shown in FIGS. 3-10). The difference is that the first trenches T1 and the second trenches T2 are alternately formed over the bit line 110 when forming the semiconductor device in FIGS. 11-12. That is, when forming the semiconductor device in FIGS. 11-12, the first trenches T1 and the second trenches T2 in FIG. 4 should be alternatively formed. Other details related to the manufacturing method of the semiconductor device in FIGS. 11-12 are similar to the manufacturing method shown in FIGS. 3-10, and are not described herein repeatedly.

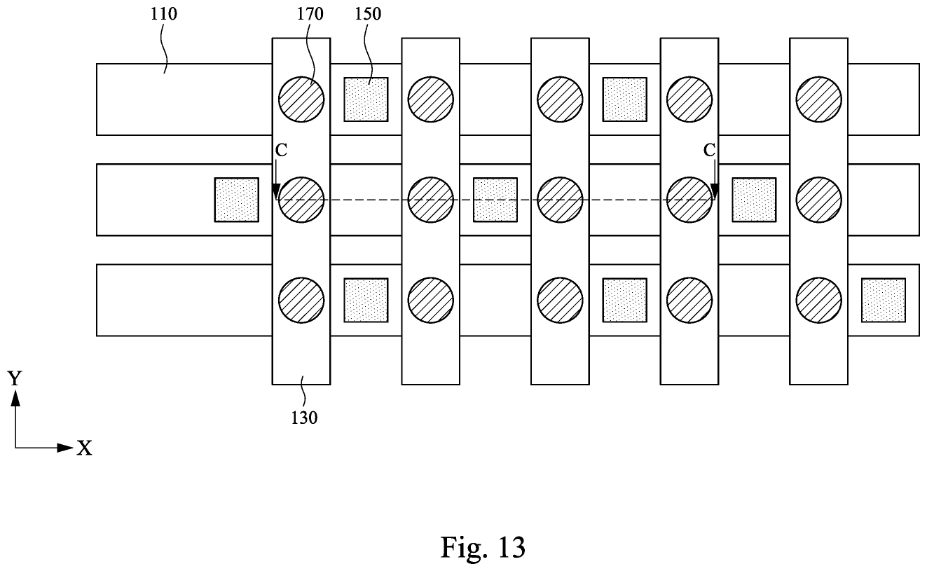

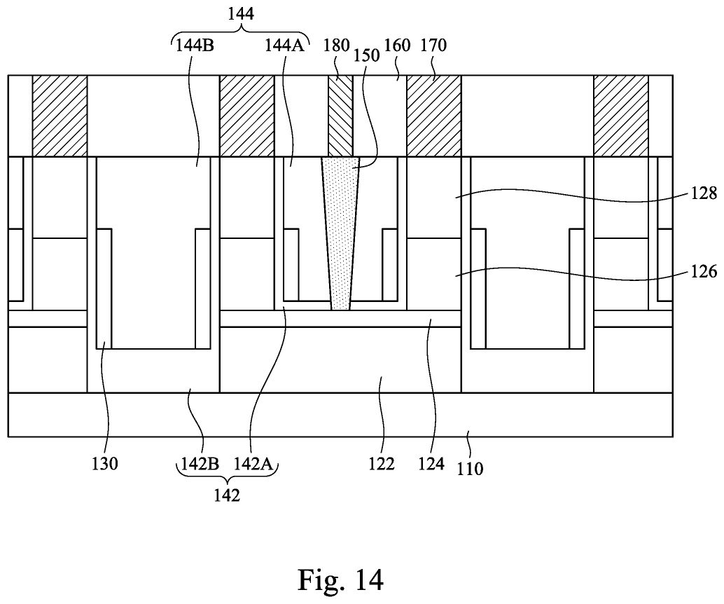

FIG. 13 illustrates a top view of a semiconductor device in some other embodiments of the present disclosure. FIG. 14 illustrates a cross-section view of the semiconductor device taken along line C-C in FIG. 13 in some other embodiments of the present disclosure. The semiconductor device in FIGS. 13-14 is similar to the semiconductor device in FIGS. 11-12. The difference is that the body contacts 150 on a first one of the bit line 110 are laterally offset from the body contacts 150 on a second one of the bit line 110 adjacent to the first one of the bit line 110 along a first direction (e.g. X-direction). The first direction (e.g. X-direction) is the longitudinal direction of the bit line 110. The first direction is perpendicular to a second direction (e.g. Y-direction), which is the longitudinal direction of the word line 130. Therefore, the semiconductor device in FIGS. 13-14 may have two different cross-section views FIG. 12 taken along line B-B and FIG. 14 taken along line C-C. The details related to the manufacturing method of the semiconductor device in FIGS. 13-14 are similar to the manufacturing method shown in FIGS. 3-10, and are not described herein repeatedly.

As mentioned above, the body contact in the semiconductor device may be used to reduce the OFF-state leakage current. More specifically, the body contact is in contact with the body, and is used to introduce the accumulated holes out of the body, so the OFF-state leakage current may be reduced. The body contact may be adjacent to one side of the channel or adjacent to two sides of the channel. In some embodiments, the body contact is made of P-type heavily doped material, the source is made of N-type heavily doped material, and the body is made of P-type lightly doped material. The source and the body contact are separated by the body. Therefore, the interface between P-type heavily doped region (i.e. body contacts) and N-type heavily doped region (i.e. source) is not existed. The OFF-state leakage current will further be reduced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor device, comprising:
a bit line;
a source on the bit line;
a body on the source;
a channel on the body;
a drain on the channel;
a word line surrounding and spaced apart from the channel; and
a first body contact on the body, wherein the first body contact and the source are separated by the body.

2. The semiconductor device of claim 1, wherein the first body contact is adjacent to a first side of the channel.

3. The semiconductor device of claim 2, further comprising a second body contact adjacent to a second side of the channel, wherein the second side is opposite to the first side.

4. The semiconductor device of claim 1, wherein a top surface of the first body contact is level with a top surface of the drain.

5. The semiconductor device of claim 1, further comprising a dielectric layer extending from a sidewall of the drain, passing through a sidewall of the channel and a top surface of the body, to the first body contact.

6. The semiconductor device of claim 5, further comprising an isolation structure surrounding the first body contact and in contact with the dielectric layer.

7. The semiconductor device of claim 6, wherein a top surface of the first body contact is level with a top surface of the isolation structure.

8. The semiconductor device of claim 1, wherein a bottom surface of the first body contact is level with a bottom surface of the channel.

9. The semiconductor device of claim 1, further comprising a capacitor on the drain.

10. The semiconductor device of claim 1, further comprising a terminal on the first body contact.

11. The semiconductor device of claim 10, wherein the first body contact extends from the body to the terminal.

12. A manufacturing method of a semiconductor device, comprising:
sequentially forming a bit line, a source, a body, a channel material layer and a drain material layer, wherein the source is on the bit line, the body is on the source, the channel material layer is on the body, and the drain material layer is on the channel material layer;
forming first trenches in the channel material layer and the drain material layer to expose the body, wherein remaining portions of the channel material layer and the drain material layer form channels and drains;
forming a dielectric layer lining the first trenches;
forming word lines surrounding the channels, wherein the word lines and the channels are separated by the dielectric layer;
forming isolation structures in the first trenches; and
forming body contacts in the isolation structures, wherein the body contacts are in contact with the body.

13. The manufacturing method of claim 12, further comprising:
forming a second trench in the source, the body, the channel material layer and the drain material layer to expose the bit line after forming the first trenches.

14. The manufacturing method of claim 12, further comprising:
forming capacitors on the drains.

15. The manufacturing method of claim 12, further comprising:
forming terminals on the body contacts.

16. The manufacturing method of claim 12, wherein forming the body contacts comprises:
forming third trenches in the isolation structures and the dielectric layer and exposing the body; and
filling a p-type heavily doped material in the third trenches to form the body contacts.

17. The manufacturing method of claim 16, wherein the body contacts are in contact with the isolation structures and the dielectric layer.

18. The manufacturing method of claim 16, wherein bottoms of the third trenches are level with bottom surfaces of the channels, so that the bottoms surfaces of the body contacts are level with bottom surfaces of the channels.

19. The manufacturing method of claim 12, wherein top surfaces of the body contacts are level with top surfaces of the drains.

20. The manufacturing method of claim 12, wherein top surfaces of the body contacts are level with top surfaces of the isolation structures.
